(19) United States
(12) Patent Application Publication
(10) Pub. No.: US 2002/0030207 A1
(43) Pub. Date: Mar. 14, 2002

(54) SEMICONDUCTOR DEVICE HAVING A CHANNEL-CUT DIFFUSION REGION IN A DEVICE ISOLATION STRUCTURE

(76) Inventors: SATOSHI TAKAHASHI, KANAGAWA (JP); MASAAKI HIGASHITANI, KANAGAWA (JP)

Correspondence Address: ARMSTRONG,WESTERMAN & HATTORI, LLP, 1725 K STREET, NW., SUITE 1000, WASHINGTON, DC, 20006, US

(21) Appl. No.: 09/301,016

(22) Filed: Apr. 28, 1999

(30) Foreign Application Priority Data
May 14, 1998 (JP) 10-132059

(51) Int. Cl. H01L 27/108

(52) U.S. Cl. 257/296

(57) ABSTRACT

A flash memory device includes a channel-cut diffusion region underneath a field oxide film wherein the channel-cut diffusion region is formed in correspondence to a gap formed between a polysilicon pattern forming a floating gate electrode and an adjacent polysilicon pattern forming an adjacent floating gate electrode, wherein the floating gate electrode carries a side wall pattern at an edge surface defining said gap and wherein the adjacent floating gate electrode carries a side wall pattern also at an edge surface defining said gap at the opposite side.

### BACKGROUND OF THE INVENTION

The present invention generally relates to semiconductor devices and more particularly to a semiconductor device having a field oxide film for device isolation.

In a semiconductor integrated circuit in which a number of semiconductor devices are integrated on a common semiconductor substrate, the semiconductor devices are generally isolated from each other by a field oxide film formed on the substrate. While a field oxide film has been formed generally by a LOCOS process with a thickness of several hundred nanometers, recent, so-called submicron or quarter-micron devices require a reduced thickness for the field oxide film as a result of the device miniaturization. On the other hand, such a reduction in the thickness of the field oxide film raises a problem in that the transfer of carriers through the region underneath the field oxide film may not be effectively suppressed. When this occurs, the desired device isolation may not be achieved. This problem becomes particularly conspicuous in flash memories or EPROMs in which a high voltage is applied to the control electrode.

In view of the foregoing, conventional highly miniaturized semiconductor integrated circuits include a channel-cut doping region in the semiconductor substrate right underneath the field oxide film so as to neutralize the carriers. Such a channel-cut doping region is formed by an ion implantation process of a suitable impurity element.

FIGS. 1A-1D, FIGS. 2A-2D, FIGS. 3A-3D and FIGS. 4A-4D show the fabrication process of a conventional flash memory 10 having a field oxide film for device isolation, wherein FIGS. 1A, 2A, 3A and 4A show the flash memory 10 in a plan view, while FIGS. 1B, 2B, 3B and 4B show a cross-sectional view taken along a line A-A′ in the plan view. Further, FIGS. 1C, 2C, 3C and 4C show a cross-sectional view taken along a line B-B′, while FIGS. 1D, 2D, 3D and 4D show a cross-sectional view taken along a line C-C′.

Referring to FIGS. 1A-1D, a p-type Si substrate 11 carries thereon a thermal oxide film 12 as a pad oxide film with a thickness of about 25 nm, and an SiN film 13 is deposited on the thermal oxide film 12 with a thickness of about 170 nm. The SiN film 13 is patterned into parallel stripes, and the Si substrate 11 is subjected to a thermal oxidation process while using the SiN film 13 as a mask. Thereby, a plurality of field oxide patterns 14 are formed so as to extend parallel with each other as indicated in FIG. 1A.

Next, in the step of FIGS. 2A-2D, the SiN film 13 and the thermal oxide film 12 are removed to expose the surface of the Si substrate 11, and a tunneling oxide film 15 is formed on the surface of the Si substrate 11 thus exposed with a thickness of about 10 nm. Further, a polysilicon film is deposited on the structure thus obtained with a thickness of about 150 nm, followed by a patterning process thereof, to form a floating gate electrode pattern 16 as indicated in FIG. 2A, wherein it can be seen that the floating gate electrode pattern 16 is defined laterally by a pair of field oxide patterns 14. It should be noted that the floating gate electrode 16 thus formed extends in the elongating direction of the field oxide patterns 14 between a pair of the field oxide patterns 14 as noted before, wherein the floating gate electrode 16 covers the edge part of the field oxide patterns 14. Thereby, there is formed a gap between a pair of mutually opposing floating gate electrode patterns 16.

Next, in the step of FIGS. 2A-2D, an ion implantation process of an impurity element is conducted in the step of FIGS. 2A-2D through the field oxide patterns 14 while using the floating gate electrode patterns 16 as a self-alignment mask, to form a channel-cut diffusion region 11a in the Si substrate 11 right underneath the field oxide patterns 14 in correspondence to the gap between the adjacent floating gate electrodes 16. The impurity element is selected such that the channel-cut region 11a disconnects the carrier path underneath the field oxide patterns 14. In a typical example of forming an N-channel transistor as a memory cell transistor of the flash memory 10, the channel-cut region 11a is formed by an ion implantation process of B⁺ conducted into the substrate 11 under an acceleration energy of 40-60 keV with a dose of 1-10×10¹³cm⁻².

Next, in the step of FIGS. 3A-3D, an interlayer insulation film 17 having a so-called ONO structure is deposited on the structure of FIGS. 2A-2D uniformly, and a conductor layer 18 having a stacking structure of a polysilicon layer and a WSi layer respectively having a thickness of about 150 nm and a thickness of about 200 nm is deposited further on the interlayer insulation film 17. It should be noted that the interlayer insulation film 17 has a stacking structure of an SiO₂ layer having a thickness of 8-10 nm, an SiN layer having a thickness of 10-12 nm, and an SiO₂ layer having a thickness of about 3 nm.

The conductor pattern 18 and the underlying interlayer insulation film 17 thus formed are subjected to a patterning process, together with the underlying floating gate electrode pattern 16, to form a gate electrode structure of the flash memory 10 extending in the elongating direction of the field oxide patterns 14. The gate electrode structure includes a floating gate electrode formed of the floating gate electrode pattern 16 and a control gate electrode formed of the conductor layer 18, wherein the floating gate electrode (designated hereinafter with the reference numeral 16) is isolated from the Si substrate 11 by the tunneling oxide film 15, while the control gate electrode (designated hereinafter by the reference numeral 18) is insulated from the floating gate electrode 16 by the interlayer insulation film 17.

Next, in the step of FIGS. 4A-4D, an ion implantation process of an impurity element such as As is conducted into the Si substrate 11 while using the control gate electrode 18 as a mask, to form source and drain regions of the memory cell transistor in the Si substrate 11. As a result of the ion implantation process, it can be seen that diffusion regions 11A-11C of the n⁺-type are formed in the substrate 11 as represented in the cross-sectional view of FIG. 4D. Further, there is provided a side wall oxide film 19 at both side walls of the gate electrode structure that includes therein the floating gate electrode 16, the interlayer insulation film 17 and the control gate electrode 18. The diffusion regions 11A-11C may be formed by an ion implantation process of As⁺ under the acceleration energy of 40-60 keV with a dose of 1-5 ×10¹⁵cm⁻².

In the flash memory 10 of the foregoing construction, the channel-cut diffusion region 11a of the p⁺-type formed in the Si substrate 11 right underneath the field oxide film 14 neutralizes the n-type carriers, i.e., the electrons, and an effective device isolation is guaranteed even in the case of a highly miniaturized flash memories characterized by a very thin field oxide patterns 14. The foregoing process of forming the flash memory 10 is advantageous in the point that there is no need of a separate mask in the ion implantation process of forming the channel-cut region 11a, and the increase of complexity in the fabrication process of the flash memory is avoided.

In the conventional flash memory 10 of FIGS. 4A-4D, it should be noted that the channel-cut diffusion region 11a is formed relatively close to the n⁺-type diffusion region 11A, 11B or 11C. See the plan view of FIG. 4A. Thereby, there is a substantial risk that the breakdown may occur easily in any of the foregoing n⁺-type diffusion regions 11A, 11B and 11C used for the source region or drain region of the flash memory 10. In FIG. 11A, the illustration of the diffusion region 11A is omitted for the sake of simplicity. In a flash memory or an EPROM, such diffusion regions are subjected to application of a high voltage when writing data or erasing data. Thus, it is important to increase the breakdown voltage for the diffusion regions 11A, 11B and 11C.

The breakdown voltage of the foregoing diffusion regions 11A, 11B and 11C are certainly increased when the distance to these diffusion regions from the channel-cut diffusion region 11a is increased. On the other hand, such an approach invites an increase in the memory cell size and is contradictory to the requirement of the device miniaturization.

Alternatively, it is possible to conduct the patterning of the floating gate electrode pattern 16 in the step of FIGS. 2A-2D such that the gap between the adjacent floating gate electrode patterns 16 is minimized. In such an approach, however, a very high-resolution is required for the photolithographic process and is vulnerable to the problem of etching residue.

### SUMMARY OF THE INVENTION

Accordingly, it is a general object of the present invention to provide a novel and useful semiconductor device and a fabrication process thereof wherein the foregoing problems are eliminated.

Another and more specific object of the present invention is to provide a semiconductor device having a channel-cut diffusion region under a field oxide film, wherein the breakdown voltage of a diffusion region of the semiconductor device in the vicinity of the channel-cut diffusion region is improved substantially.

Another object of the present invention is to provide semiconductor device, comprising:

a substrate;

a field oxide film formed on said substrate so as to define an active region on said substrate;

a tunneling insulation film covering said active region;

a gate structure formed on said tunneling insulation film; and

a pair of diffusion regions having a first conductivity type formed in said active region of said substrate at both lateral sides of said gate structure;

said gate structure including a floating gate electrode formed on said tunneling insulation film, an interlayer insulation film covering said floating gate electrode, and a control electrode formed on said interlayer insulation film so as to sandwich said interlayer insulation film between said control electrode and said floating gate electrode;

said floating gate electrode extending over said active region to said field oxide film, said floating gate electrode having an end surface located on said field oxide film;

said floating gate electrode further carrying a side wall pattern on said end surface, said side wall pattern extending laterally from said end surface and having an apex at a tip end thereof;

said substrate further including a channel-cut diffusion region having a second conductivity type in correspondence to a tip end of said side wall pattern.

According to the present invention, it becomes possible to form a channel-cut diffusion region in an extremely narrow area of the semiconductor device underneath the field oxide film, by conducting an ion implantation process through the field oxide film while using the conductive patterns, from which a gate electrode or a floating gate electrode is formed, as a mask. The conductive patterns carry, on an end surface thereof, a side wall pattern so as to narrow the mask opening through which the ion implantation process is conducted. The side wall patterns can be formed by a self-alignment process, without complicating the fabrication process of the semiconductor device. By using the side wall patterns for narrowing the mask opening, the patterning process of the conductive patterns is facilitated substantially.

By using the present invention in a flash memory or an EPROM having a floating gate electrode, the problem of drain breakdown, which tends to occur as a result of the device miniaturization, is effectively eliminated. Further, the use of the side wall patterns provides an additional advantageous effect of increase in the coupling capacitance between the floating gate electrode and the control electrode. As the side wall pattern generally have an inclined surface, the interlayer insulation film covering such a side wall pattern is positively removed by a dry etching process, without leaving an unetched pattern. Further, the step coverage of the control electrode provided on the interlayer insulation film is improved due to the existence of the side wall patterns.

Other objects and further features of the present invention will become apparent from the following detailed description when read in conjunction with the attached drawings.

### BRIEF DESCRIPTION OF THE DRAWINGS

FIGS. 1A-1D are diagrams showing a fabrication step of a conventional flash memory respectively in a plan view and different cross-sectional views;

FIGS. 2A-2D are diagrams showing a fabrication step of the conventional flash memory following the fabrication step of FIGS. 1A-1D respectively in a plan view and different cross-sectional views;

FIGS. 3A-3D are diagrams showing a fabrication step of the conventional flash memory following the fabrication step of FIGS. 2A-2D respectively in a plan view and different cross-sectional views;

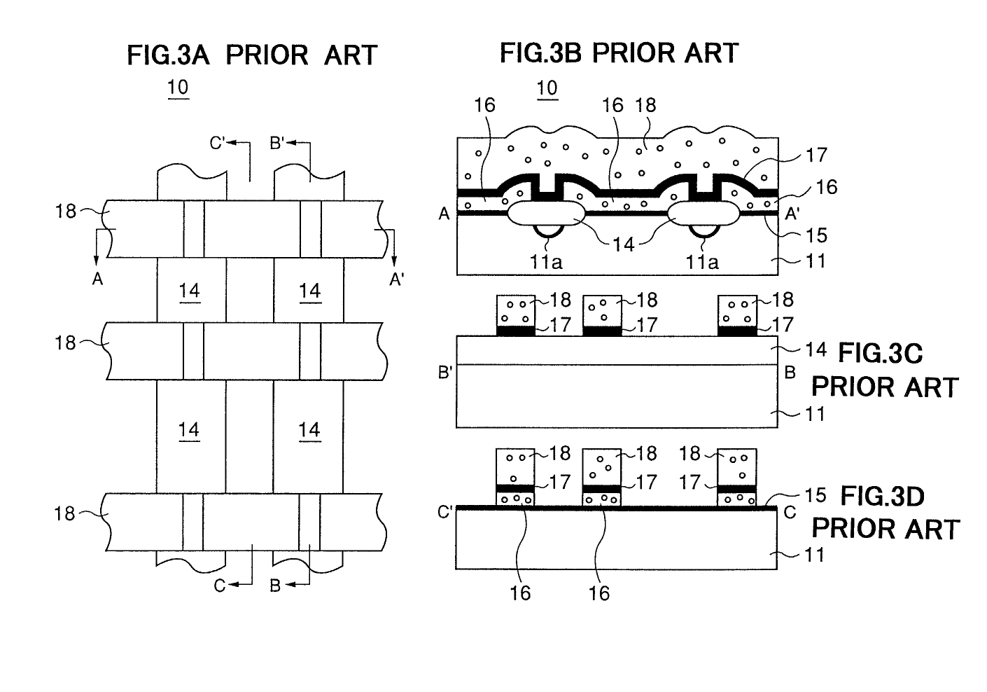

FIGS. 4A-4D are diagrams showing a fabrication step of the conventional flash memory following the fabrication step of FIGS. 3A-3D respectively in a plan view and different cross-sectional views;

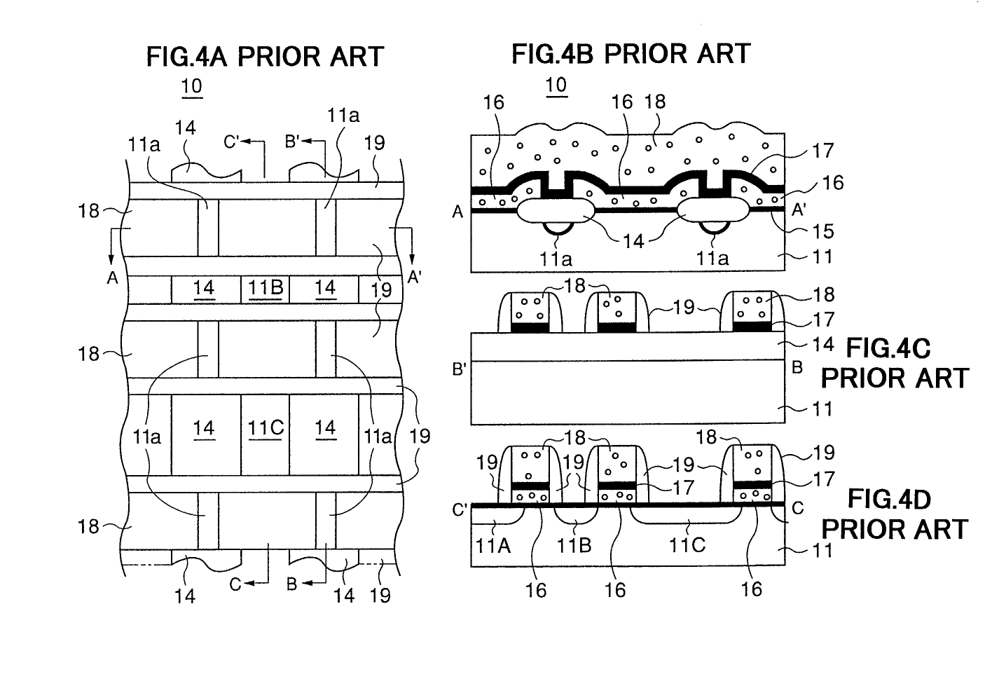

FIGS. 5A-5D are diagrams showing a fabrication step of a flash memory according to a first embodiment of the present invention respectively in a plan view and different cross-sectional views;

FIGS. 6A-6D are diagrams showing a fabrication step of the flash memory of the first embodiment following the fabrication step of FIGS. 5A-5D respectively in a plan view and different cross-sectional views;

FIGS. 7A-7D are diagrams showing a fabrication step of the flash memory of the first embodiment following the fabrication step of FIGS. 6A-6D respectively in a plan view and different cross-sectional views;

FIGS. 8A-8D are diagrams showing a fabrication step of the flash memory of the first embodiment following the fabrication step of FIGS. 7A-7D respectively in a plan view and different cross-sectional views;

FIGS. 9A-9D are diagrams showing a fabrication step of the flash memory of the first embodiment following the fabrication step of FIGS. 8A-8D respectively in a plan view and different cross-sectional views;

FIGS. 10A-10D are diagrams showing a fabrication step of the flash memory of the first embodiment following the fabrication step of FIGS. 9A-9D respectively in a plan view and different cross-sectional views;

FIG. 11 is a diagram showing the construction of a flash memory of the first embodiment in the completed state;

FIGS. 12A and 12B are diagrams explaining the process of forming a side wall pattern used in the first embodiment of the present invention;

FIG. 13 is a diagram explaining the process of forming a slanted end surface for a conductor pattern used in the first embodiment;

FIG. 14 is a diagram showing a fabrication step of a DRAM according to a second embodiment of the present invention in a plan view;

FIG. 15 is a diagram showing a fabrication step of the DRAM of the second embodiment following the fabrication step of FIG. 14 in a plan view;

FIG. 16 is a diagram showing a fabrication step of the DRAM of the second embodiment following the fabrication step of FIG. 15 in a plan view;

FIG. 17 is a diagram explaining the fabrication step of FIG. 16; and

FIG. 18 is a diagram showing the construction of the DRAM of the second embodiment in a completed state.

### DETAILED DESCRIPTION OF THE PREFERRED EMBODIMENTS

### First Embodiment

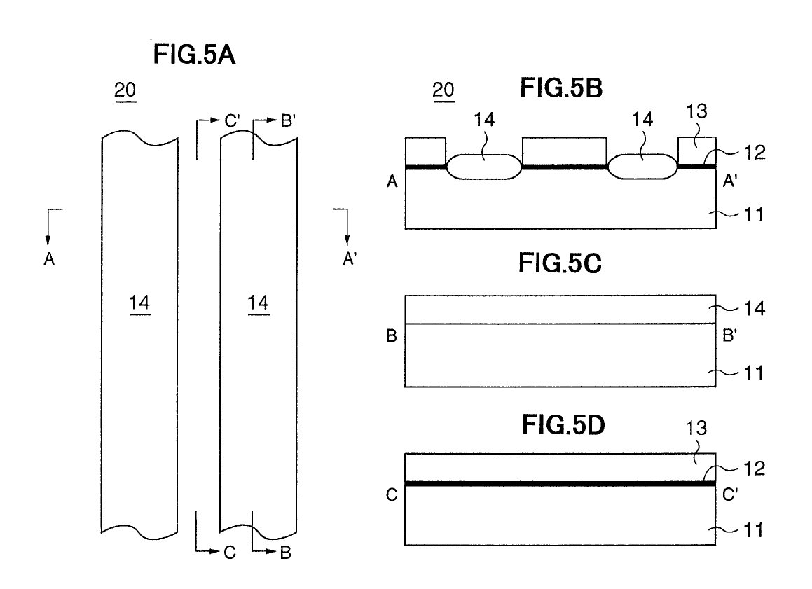

FIGS. 5A-5D, FIGS. 6A-6D, FIGS. 7A-7D, FIGS. 8A-8D, FIGS. 9A-9D, and FIGS. 10A-10D show the fabrication process of a flash memory 20 according to a first embodiment of the present invention, wherein FIGS. 5A, 6A, 7A, 8A, 9A and 10A represent a plan view, FIGS. 5B, 6B, 7B, 8B, 9B and 10B show a cross-sectional view taken along a line A-A′ represented in the plan views; FIGS. 5C, 6C, 7C, 8C, 9C and 10C show a cross-sectional view taken along a line B-B′ represented in the plan views; and FIGS. 5D, 6D, 7D, 8D, 9D and 10D show a cross-sectional view taken along a line C-C′ represented in the plan views. In the drawings, those parts corresponding to the parts described previously are designated by the same reference numerals and the description thereof will be omitted.

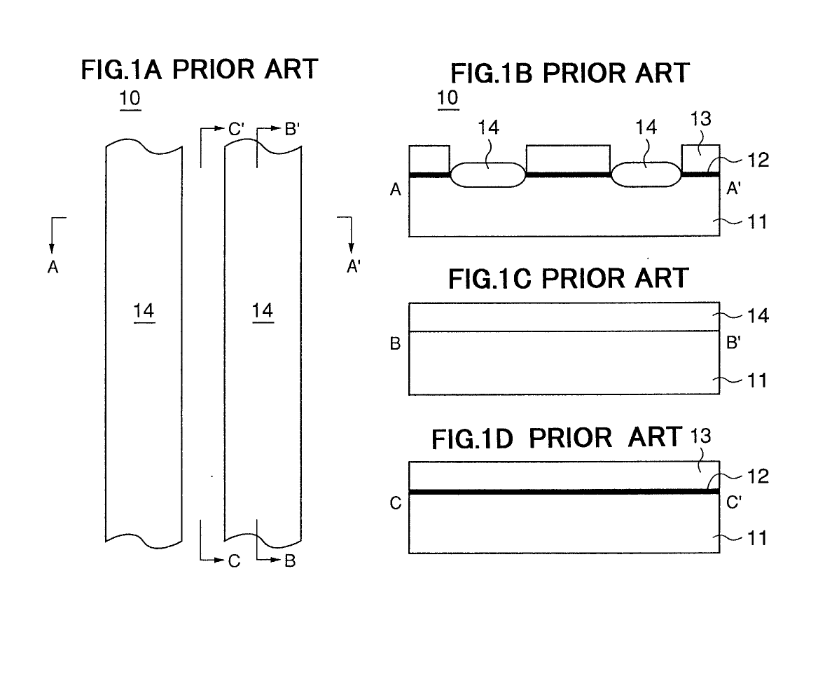

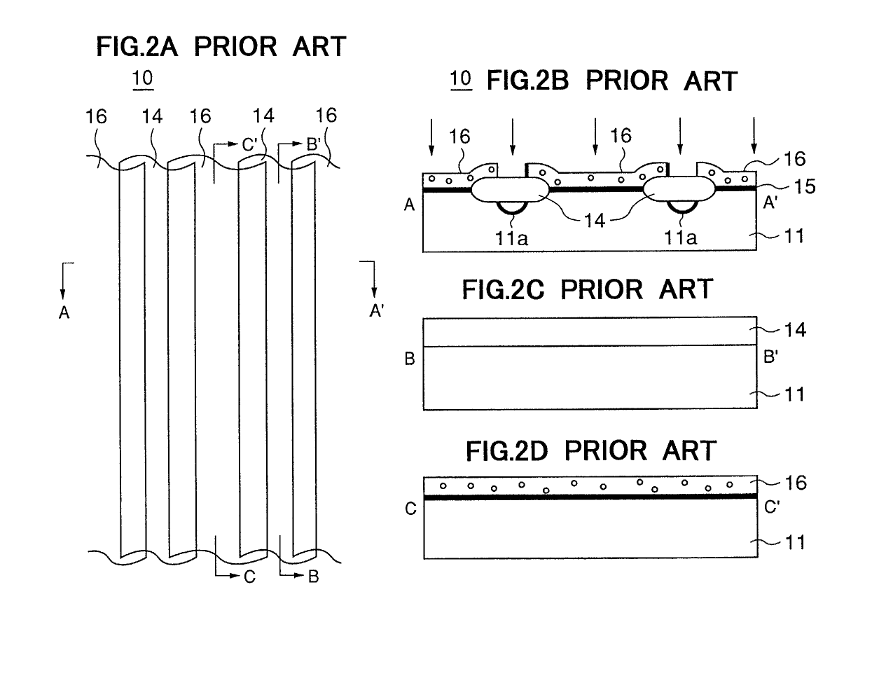

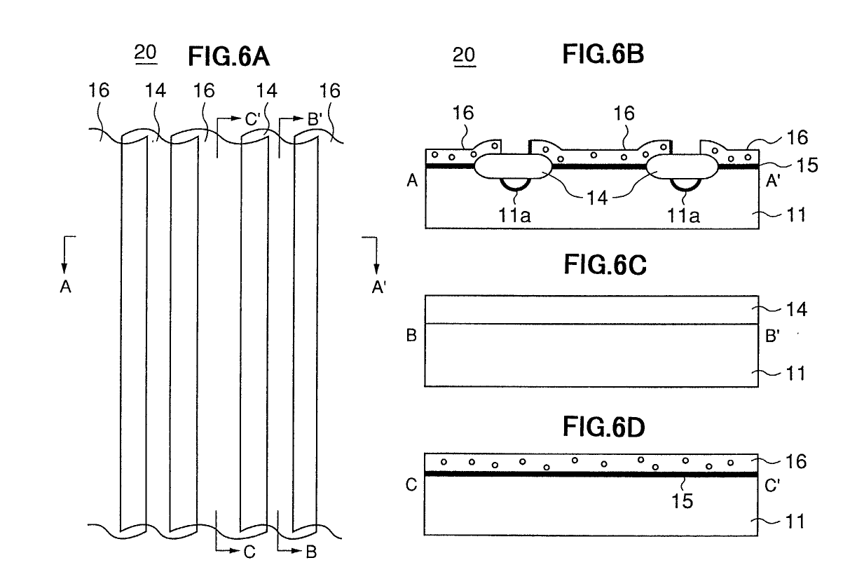

Referring to the drawings, the process steps of FIGS. 5A-5D and FIGS. 6A-6D are substantially identical with the process steps of FIGS. 1A-1D and FIGS. 2A-2D explained before, and the field oxide patterns 14 are formed on the Si substrate 11 in the form of parallel stripes. Further, the polysilicon patterns 16 are formed also in parallel stripes extending parallel to the field oxide patterns 14. Similarly to the conventional process steps, each of the polysilicon patterns 16 has an end surface extending parallel with the field oxide patterns 14, wherein the end surface faces the end surface of an adjacent polysilicon pattern 16 on the field oxide pattern 14 with an intervening gap therebetween. In the present embodiment, on the other hand, the ion implantation process is not conducted in the state of FIGS. 6A-6D, contrary to the step of FIGS. 2A-2D.

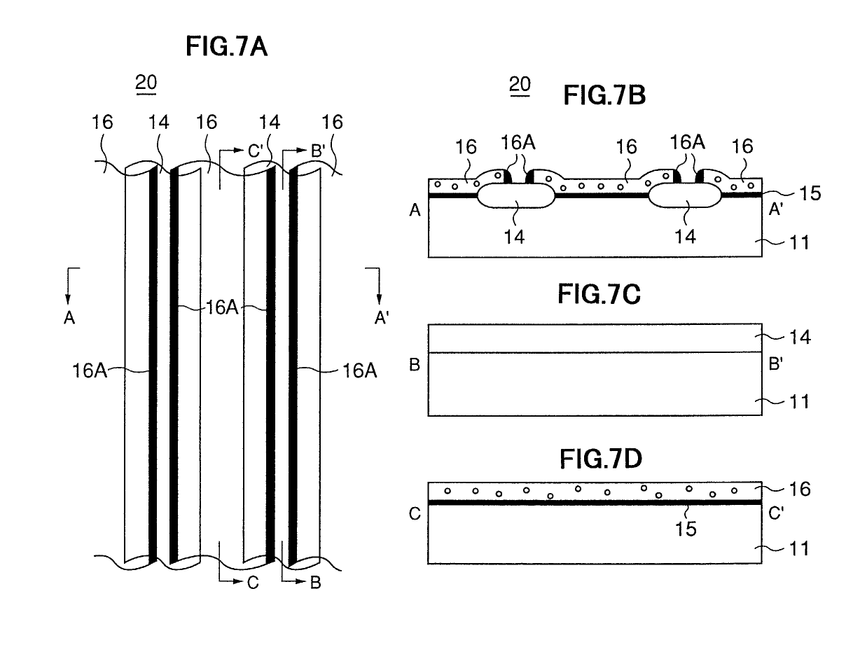

Next, in the step of FIGS. 7A-7D, side wall patterns 16A are formed on the foregoing end surface of the polysilicon patterns 16. As will be explained later in detail, the side wall patterns 16A are formed by a deposition process of a polysilicon layer, followed by an etch back process.

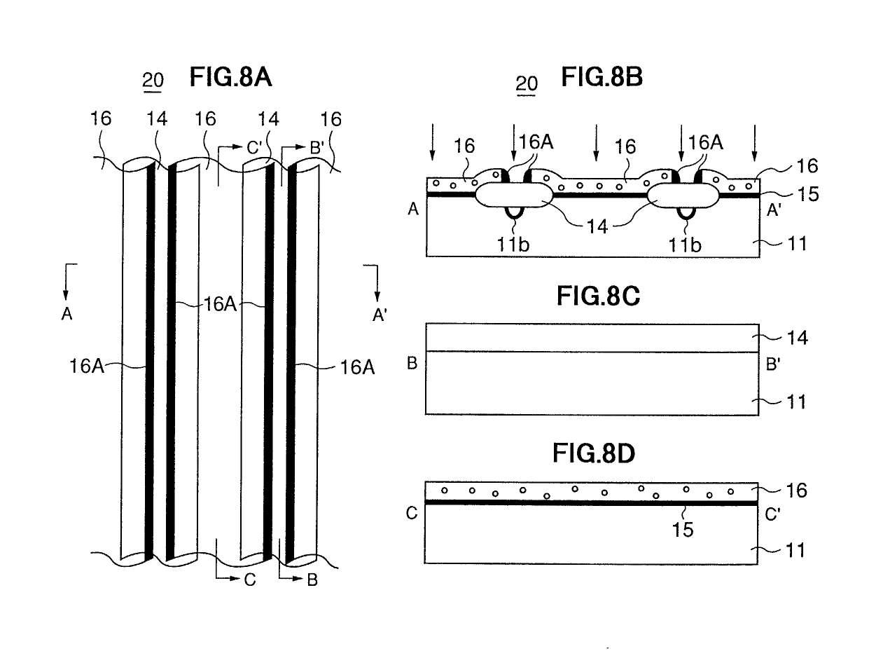

Next, in the step of FIGS. 8A-8D, the polysilicon patterns 16 and the polysilicon side wall patterns 16A are used as a self-aligned mask, and an ion implantation process of B⁺ is conducted through the foregoing self-alignment mask under an acceleration energy of typically 40-60 keV and a dose of 1-10×10¹³cm⁻². As a result of the ion implantation process thus conducted, a channel-cut diffusion region 11b is formed in the substrate 11 in correspondence to the conventional channel-cut diffusion region 11a, wherein it should be noted that the channel-cut diffusion region 11b has a reduced width as compared with the channel-cut diffusion region 11a due to the use of the side wall patterns 16A in the ion implantation process of B⁺ as the mask.

Next, in the step of FIGS. 8A-8D, the interlayer insulation film 17 is formed on the structure of FIGS. 8A-8D similarly as before, and the conductor layer 18 having a stacked structure of a polysilicon layer and a WSi layer is deposited on the interlayer insulation film 17. The conductor layer 18 and the interlayer insulation film 17 and further the polysilicon layer underneath the interlayer insulation film 17 are then patterned to form a gate structure extending in the direction generally perpendicular to the elongating direction of the field oxide patterns 14, wherein it will be noted that the polysilicon layer 16 form, after the patterning process, a floating gate electrode, which is isolated from other floating gate electrodes. On the other hand, the conductor layer 18 form a control electrode extending over a number of the floating gate electrodes.

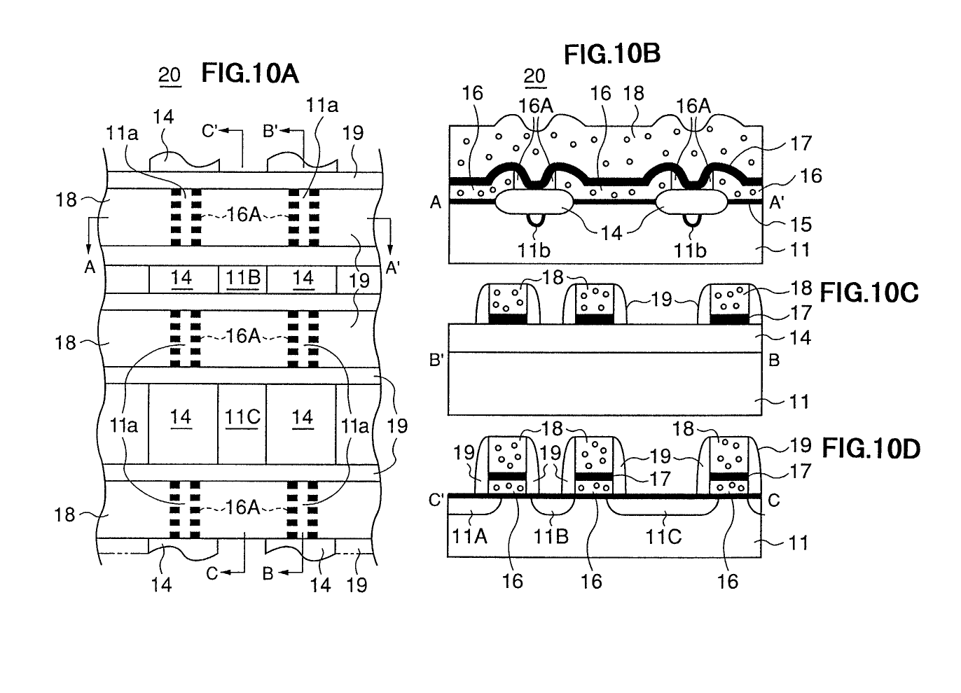

Next, in the step of FIGS. 10A-10D, the gate structure thus formed is used for a self-alignment mask, and an ion implantation process of As⁺ is conducted into the Si substrate 11 under an acceleration energy of 40-60 keV with a dose of 1-5×10¹³cm⁻². As a result of the ion implantation process, the diffusion regions 11A, 11B and 1C, all of the n⁺-type, are formed adjacent to the gate structure. Further, side wall oxide films 19 are formed on each of the gate structures.

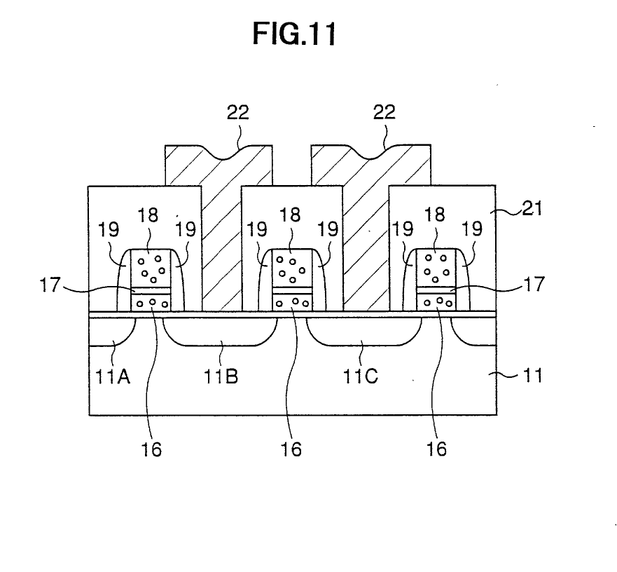

Finally, the structure of FIGS. 10A-10D is covered by an interlayer insulation film 21 as indicated in FIG. 11 and ohmic electrodes 22 are provided on the interlayer insulation film 21 in ohmic contact with the diffusion regions 11A, 11B and 11C through respective contact holes formed in the interlayer insulation film 21.

As explained previously, the ion implantation process for forming the channel-cut diffusion region 11b is conducted while using the polysilicon side wall pattern 16A on the end surface of the polysilicon pattern 16 as a mask. Thereby, the width of the channel-cut diffusion region 11b is reduced substantially, and the problem of decrease of the drain breakdown voltage is successfully avoided even when a further miniaturization is made in the flash memory 20.

As represented in FIG. 10B, the interlayer insulation film 17 covers the inclined surface of the polysilicon side-wall pattern 16A and the control electrode 18 covers the interlayer insulation film 17 continuously also over the part of the interlayer insulation film 17 covering the polysilicon side-wall pattern 16A. Thereby, the coupling capacitance between the control electrode 18 and the floating gate electrode 16 is increased by the amount corresponding to the area of the polysilicon side wall pattern 16A.

In the step of FIGS. 6A-6D of the present embodiment, it should be noted that the polysilicon patterns 16 may be patterned with a less strict rule as compared with the conventional patterning process of FIGS. 2A-2D, as the gap between the mutually adjacent polysilicon patterns 16 is narrowed, in the case of the present embodiment, by the side wall patterns 16A. Thereby, the throughput of production of the semiconductor device is improved substantially.

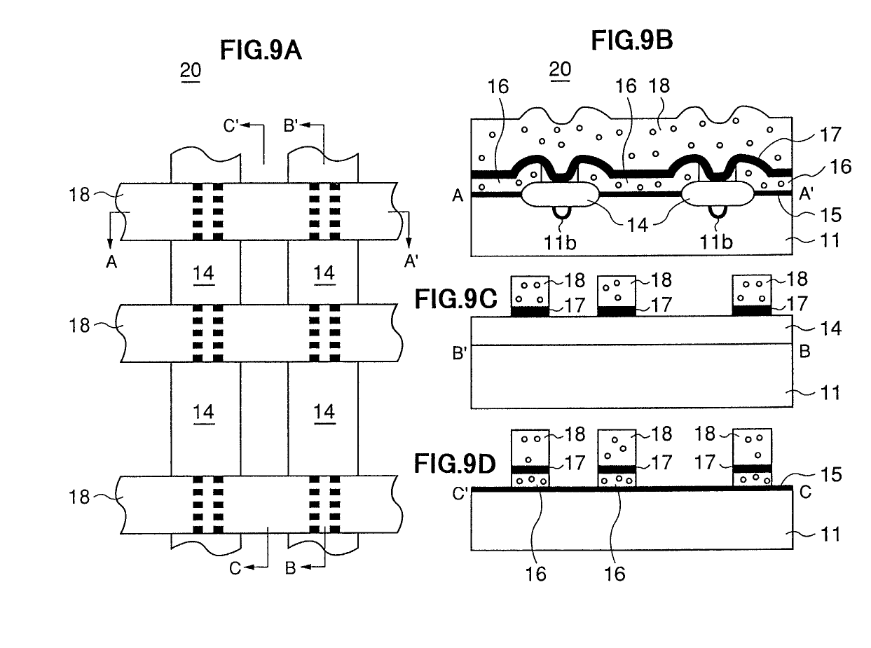

Further, in view of the fact that the interlayer insulation film 17 is deposited on the inclined surface of the polysilicon side wall patterns 16A, the problem of residue formation caused as a result of incomplete patterning of the interlayer insulation film 17 is effectively reduced as compared with the case in which the interlayer insulation film 17 covers a vertical end surface of the polysilicon patterns 16, and the problem of residue formation in the step of FIGS. 9A-9D for patterning the gate structure is successfully eliminated. Associated with this, the polysilicon patterns 16 are patterned perfectly without leaving a residue, and the problem of short circuit between adjacent floating gate electrodes 16 is effectively eliminated. Further, the problem of short circuit, caused by the polysilicon reside between the floating gate electrode 16 and the control electrode 18 is eliminated.

As can be seen in the cross-sectional view of FIG. 9B or FIG. 10B, the side wall pattern 16A improves the step coverage of the conductor layer 18, which constitutes the control electrode, over the interlayer insulation film 17 significantly. As a result of the improved step coverage of the conductor layer 18, the thickness of the conductor layer 18 is maintained substantially constant in the gap part between a pair of mutually adjacent floating gate electrode patterns 16. Thereby, there is formed a depression on the surface of the conductor layer 18 in correspondence to the side wall patterns 16A.

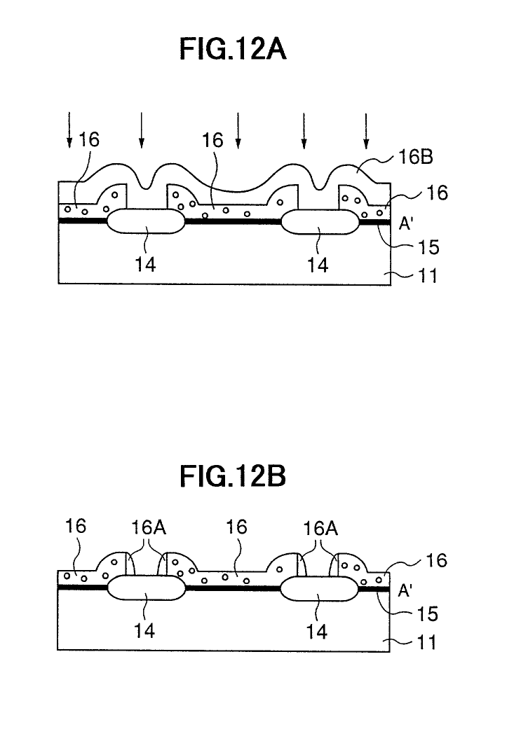

FIGS. 12A and 12B show the process of the formation of the side wall patterns 16A.

Referring to FIG. 12A, a polysilicon layer 16B is deposited on the structure of FIG. 6B uniformly, followed by an etch back process conducted by a dry etching process acting substantially perpendicularly to the principal surface of the substrate 11. By continuing the etch back process until the field oxide pattern 14 is exposed as indicated in FIG. 12B, the side wall patterns 16A are obtained so as to cover the foregoing end surfaces of the polysilicon patterns 16.

In the present embodiment, it is also possible to use an SiO₂ film in place of the polysilicon layer 16B. In this case, too, the drain breakdown characteristic of the flash memory 20 is improved by narrowing the width of the channel-cut diffusion region 11b. On the other hand, the effect of improvement of the coupling capacitance explained before is not achieved in this modification, as the side wall patterns 16A is formed of SiO₂. On the other hand, the advantage of improved step coverage of the control electrode 18 is still maintained in the present modification.

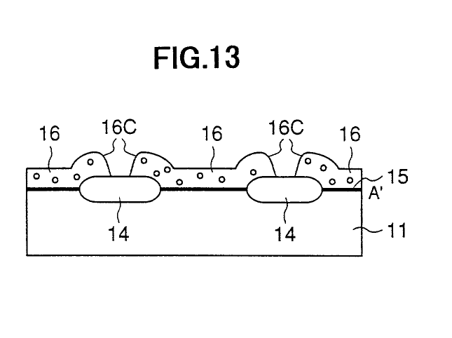

In the present embodiment, it should be noted that the narrowing of the gap formed between the polysilicon patterns 16 in the ion implantation process of FIGS. 8A-8D, is by no means limited to the formation of the side wall patterns 16A. As represented in FIG. 13, the floating gate electrode 16 may be patterned so as to have an inclined end surface 16C with respect to the principal surface of the substrate 11. The formation of such an inclined surface 16C is typically achieved by a dry etching process that uses a mixed gas of Cl₂ and O₂ as an etching gas, by setting the oxygen flow rate larger than usual. Alternatively, the inner pressure of the etching chamber may be set higher than usual.

### Second Embodiment

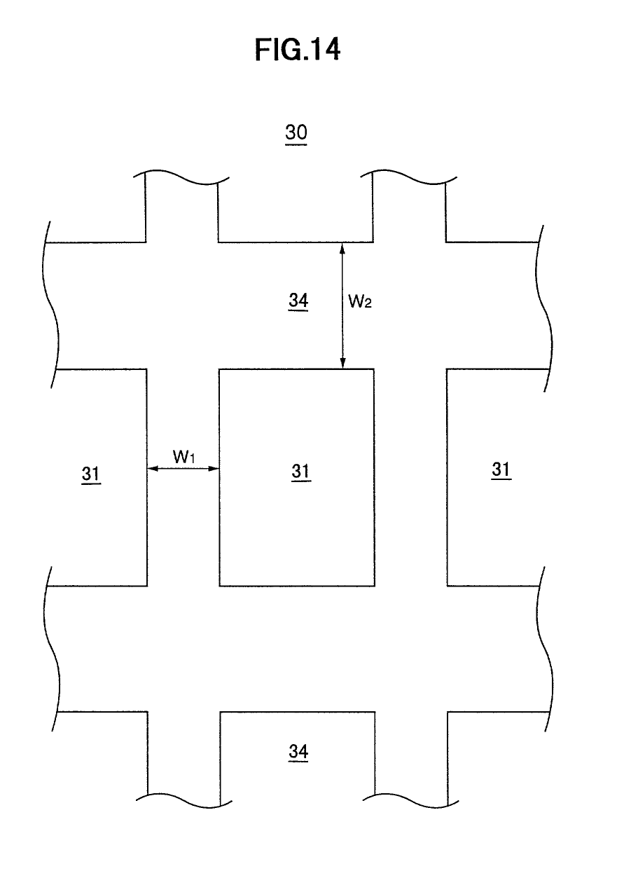

FIGS. 14-17 show the fabrication process of a DRAM 30 according to a second embodiment of the present invention.

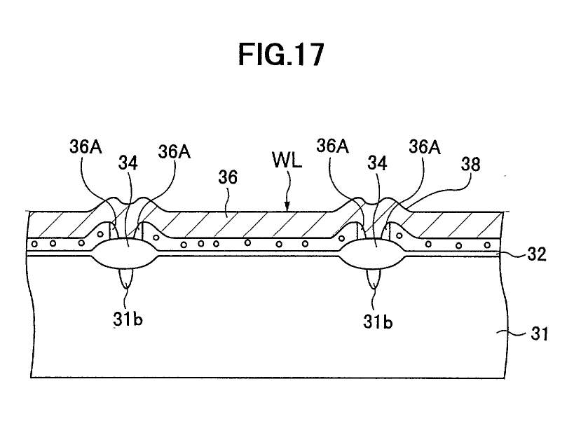

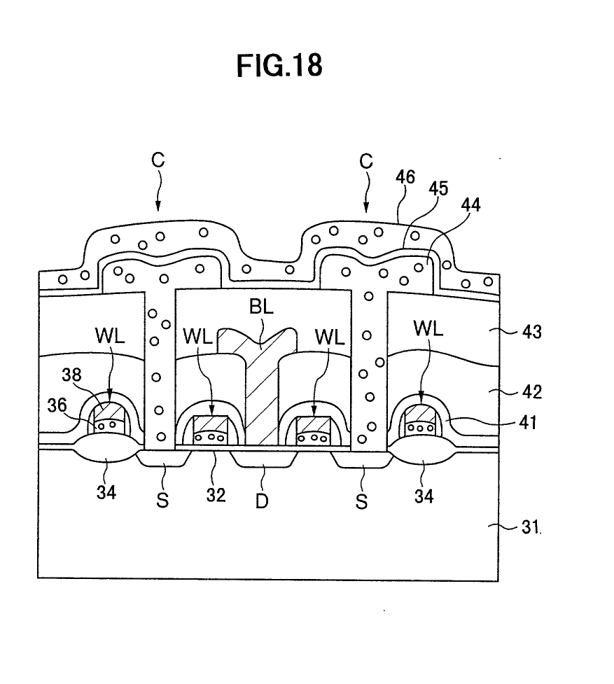

Referring to FIG. 14, a Si substrate 31 carries thereon a field oxide film 34 having a lattice pattern in place of the field oxide film 14, and a gate oxide film 32 covers the surface of the active region defined by the field oxide pattern 34. The gate oxide film 32 is shown in FIG. 17 or 18 but not in FIG. 14.

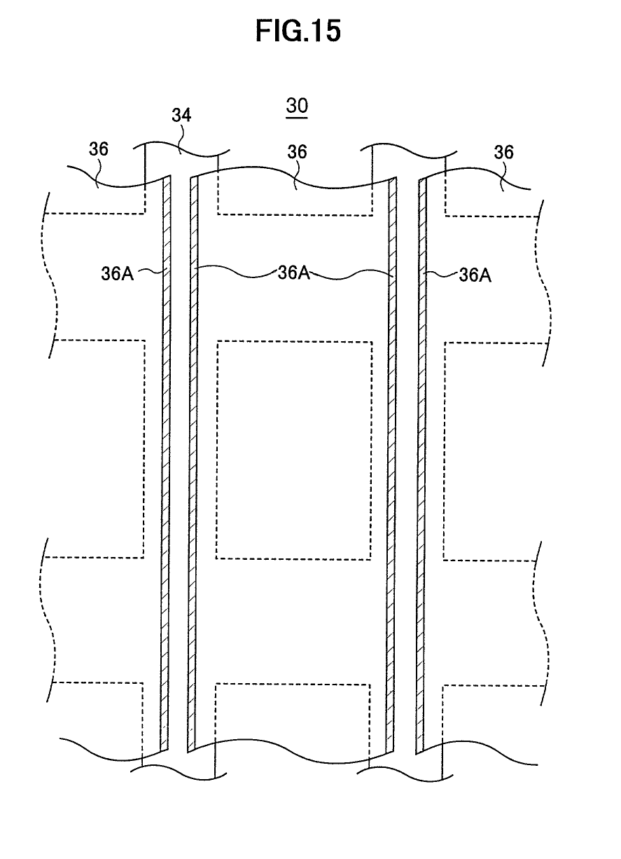

Next, in the step of FIG. 15, a polysilicon layer 36 is deposited on the Si substrate 31 so as to cover the field oxide pattern 34, and the polysilicon layer 36 thus deposited is patterned subsequently to form a number of polysilicon patterns designated by the reference numeral 35, such that the polysilicon patterns 36 extend parallel with each other similarly to the polysilicon patterns 16. Thereby, an end surface of a polysilicon pattern 36 faces a corresponding end surface of an adjacent polysilicon pattern 36 on the field oxide pattern 24, and each end surface carries thereon a polysilicon side wall pattern 36A corresponding to the polysilicon side wall pattern 16A of the previous embodiment.

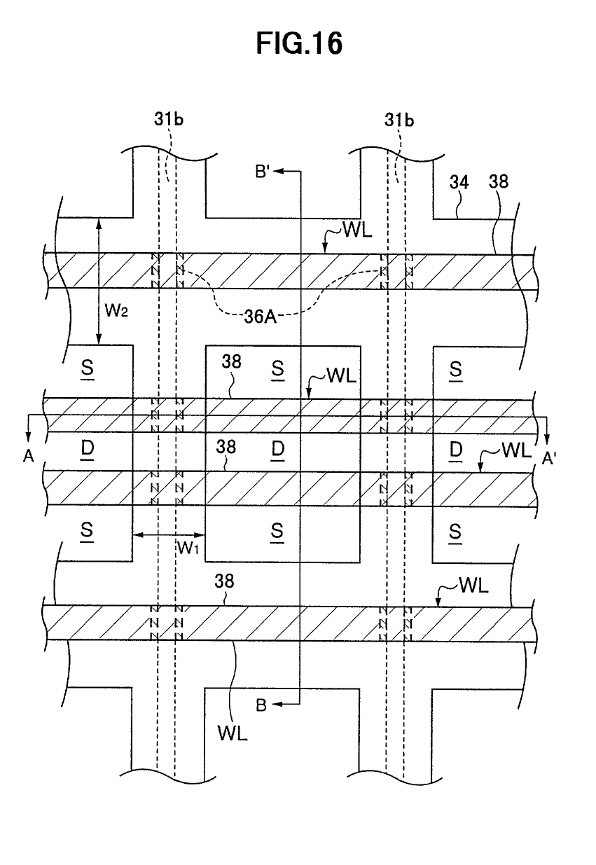

Next, in the step of FIG. 16, an ion implantation process of B⁺ is conducted while using the polysilicon patterns 36 and the side wall patterns 36A, to form a channel-cut diffusion region 31b of the p⁺-type in the substrate 31 in correspondence to the channel cut region 11b of the previous embodiment.

In the step of FIG. 16, a conductor layer 38 corresponding to the conductor layer 18 of the previous embodiment is deposited uniformly on the polysilicon pattern 36 as represented in FIG. 17, followed by a patterning process of the conductor layer 38 and the underlying polysilicon pattern 36, to form a plurality of word line patterns WL such that the word line patterns WL extend generally perpendicularly to the elongating direction of the polysilicon patterns 26 as represented in FIG. 16.

In the step of FIG. 16, the foregoing word line patterns WL are used as a self-aligned mask, to conduct an ion implantation process of As⁺ or P⁺ into the Si substrate 21. Thereby, diffusion regions S and D are formed adjacent to each of the foregoing word line patterns WL.

FIG. 17 shows the structure of FIG. 16 in a cross-sectional view taken along the line A-A′.

Referring to FIG. 17, the polysilicon pattern 36 is divided into a plurality of pattern segments each corresponding to one of the active regions, wherein a polysilicon pattern segment 36 and an adjacent polysilicon pattern segment 36 are electrically connected with each other by the conductor layer 38 that forms the word line WL extending over the substrate 21 continuously.

By depositing an interlayer insulation film on the structure of FIGS. 16 and 17 and by forming a bit line pattern and a memory cell capacitor according to a known method, a DRAM structure shown in FIG. 18 is obtained, wherein it should be noted that FIG. 18 shows the DRAM structure in a cross-sectional view taken along a line B-B′ of FIG. 16.

Referring to FIG. 18, the substrate 31 carries thereon the field oxide pattern 34 and the gate oxide film 32, and the word line pattern WL extends over the field oxide pattern 34 and the gate oxide film 32 in a direction generally perpendicular to the plane of FIG. 18. Further, the diffusion regions S and D are formed in the substrate 31.

Each of the word line patterns WL includes a stacking of the foregoing polysilicon pattern segment 36 and the continuous conductor pattern 38, and the word line patterns WL are covered by a CVD-SiO₂ film 31. Further, a BPSG film 32 covers the CVD-SiO₂ film 31.

The BPSG film 32 has a planarized top surface and is formed with a contact hole exposing the diffusion region D. The contact hole thereby includes an electrode pattern constituting the bit line pattern BL of the DRAM.

The BPSG film 32 is covered by another BPSG film 33 that covers the bit line pattern BL, and the BPSG film 33 is formed with a contact hole exposing the diffusion region S through the underlying BPSG film 32. Thereby, a known memory cell capacitor C is formed on the BPSG film 33 in contact with the diffusion region S. It should be noted that the memory cell capacitor C includes a polysilicon accumulation electrode 34 contacting with the diffusion region S and an opposing electrode 36, with an intervening capacitor insulation film 35 having an ONO structure.

In the DRAM of the present embodiment, the channel-cut diffusion region 31b cannot be formed under the part of the lattice-shaped field oxide pattern 24 extending in the direction of the word line WL. On the other hand, it is possible to form such a channel-cut diffusion region 31b underneath the lattice-shaped field oxide pattern 24 in the part thereof extending perpendicularly to the word line pattern WL. Thereby, because of the existence of the channel-cut diffusion region 31b, the width W₁ of the field oxide pattern 24 (see FIG. 14) can be reduced without sacrificing the drain breakdown characteristic of the DRAM. Further, the width W₂ of the field oxide pattern 24 can also be reduced substantially although the width W₂ cannot be reduced below the width W₁.

Further, the present invention is not limited to the embodiments described heretofore, but various variations and modifications may be made without departing from the scope of the invention.

What is claimed is

1. A semiconductor device, comprising:
a substrate;
a field oxide film formed on said substrate so as to define an active region on said substrate;
a gate insulation film covering said active region;
a gate electrode formed on said gate insulation film; and
a pair of diffusion regions having a first conductivity type formed in said active region of said substrate at both lateral sides of said gate electrode;
said gate electrode extending over said active region to said field oxide film, said gate electrode having an end surface located on said field oxide film;
said gate electrode further carrying a side wall pattern on said end surface, said side wall pattern extending laterally from said end surface and having an apex at a tip end thereof;
said substrate further including a channel-cut diffusion region having a second conductivity type in correspondence to a tip end of said side wall pattern.

2. A semiconductor device as claimed in claim 1, wherein said end surface of said gate electrode faces a corresponding end surface of an adjacent gate electrode on said field oxide film, said adjacent gate electrode being formed on an adjacent active region across said field oxide film, said end surface of said adjacent gate electrode carrying an adjacent side wall pattern facing said side wall pattern on said end surface of said gate electrode, said channel-cut diffusion region being formed between said spacer pattern of said gate electrode and said adjacent spacer pattern of said adjacent gate electrode.

3. A semiconductor device as claimed in claim 2, further including: an interlayer insulation film covering said gate electrode and said adjacent gate electrode including said side wall pattern and said adjacent side wall pattern; and a control electrode covering said gate electrode and said adjacent gate electrode continuously but separated therefrom by said interlayer insulation film.

4. A semiconductor device as claimed in claim 1, wherein said side wall pattern has a slanted surface with respect to a principal surface of said substrate.

5. A semiconductor device as claimed in claim 1, wherein said end surface of said gate electrode crosses with a principal surface of said substrate substantially perpendicularly.

6. A semiconductor device as claimed in claim 1, wherein said gate electrode and said side wall pattern are formed of polysilicon.

7. A semiconductor device as claimed in claim 1, wherein said side wall pattern is formed of an insulating material.

8. A semiconductor device, comprising:
a substrate;
a field oxide film formed on said substrate so as to define an active region on said substrate;
a tunneling insulation film covering said active region;
a gate structure formed on said tunneling insulation film; and
a pair of diffusion regions having a first conductivity type formed in said active region of said substrate at both lateral sides of said gate structure;
said gate structure including a floating gate electrode formed on said tunneling insulation film, an interlayer insulation film covering said floating gate electrode, and a control electrode formed on said interlayer insulation film so as to sandwich said interlayer insulation film between said control electrode and said floating gate electrode;
said floating gate electrode extending over said active region to said field oxide film, said floating gate electrode having a slanted end surface located on said field oxide film, such that a bottom part of said slanted end surface projects laterally beyond a top part of said slanted end surface;
said substrate further including a channel-cut diffusion region having a second conductivity type in corresponding to a tip end of said slanted surface.

9. A semiconductor device, comprising:
a substrate;
a field oxide film formed on said substrate so as to define an active region on said substrate;
a gate insulation film covering said active region;
a gate structure formed on said gate insulation film; and
a pair of diffusion regions having a first conductivity type formed in said active region of said substrate at both lateral sides of said gate structure;
said gate structure including a gate electrode formed on said gate insulation film and a gate interconnection electrode formed on said gate electrode;
said gate electrode extending over said active region to said field oxide film, said gate electrode having an end surface located on said field oxide film and facing a corresponding end surface of another gate electrode extending to said field oxide film from an adjacent active region isolated by said field oxide film;
said end surface of said gate electrode carrying a side wall pattern thereon such that said side wall pattern extends laterally from said end surface;
said end surface of said another gate electrode carrying another side wall pattern thereon such that said another side wall pattern extends laterally from said end surface;
said substrate further including a channel-cut diffusion region having a second conductivity type in correspondence to a gap formed between a tip end of said side wall pattern and a tip end of said another side wall pattern;
said gate interconnection electrode extending from said gate electrode to said another gate electrode.

10. A semiconductor device as claimed in claim 9, wherein said semiconductor device further includes a capacitor in contact with one of said diffusion regions.

11. A method of fabricating a semiconductor device, comprising the steps of:
forming a plurality of field insulation patterns on a substrate such that each of said field insulation patterns extends in a first direction;
forming a tunneling insulation film on each of active regions, said active regions being defined on said substrate between said plurality of field insulation films;
forming a conductive layer on said substrate so as to cover said plurality of field insulation patterns and said tunneling insulation films covering said active regions;
patterning said conductive layer to form a plurality of conductive patterns each extending in said first direction in correspondence to one of said plurality of active regions, said step of patterning being conducted such that each conductive pattern has an end surface located on said field oxide film and extending in said first direction, and such that said end surface faces an end surface of another conductive pattern corresponding to an adjacent active region locating across said field oxide film with a gap therebetween;
forming a side wall pattern on said end surface for each of said polysilicon patterns such that said side wall pattern projects from said end surface;
introducing an impurity element of a first conductivity type into said substrate through said field oxide patterns by an ion implantation process while using said plurality of conductive patterns and said side wall patterns as a mask;
depositing an interlayer insulation film on said substrate such that said interlayer insulation film covers said plurality of conductive patterns and said side wall patterns;
depositing a conductor layer on said interlayer insulation film generally with a uniform thickness;
patterning said conductor layer, said interlayer insulation film and further said conductive patterns underneath said interlayer insulation film, to form a plurality of gate electrode structures such that each of said gate electrode structures extends in a second direction different from said first direction, each of said gate electrode structures thereby including a floating gate electrode patterned from said conductive pattern and a control electrode patterned from said conductor layer and extending in said second direction over a plurality of said active regions, said floating gate electrode being provided in correspondence to one of said active regions and isolated from other said floating gate electrodes; and
introducing an impurity element of a second conductivity type into said substrate in each of said plurality of active regions by an ion implantation process while using said gate electrode structure as a mask, to form a diffusion region in said substrate.

12. A method as claimed in claim 11, wherein said step of forming said side wall pattern includes the steps of depositing a conductor layer such that said conductor layer covers said plurality of conductive patterns including said end surfaces and such that said conductor layer fills said gap, and applying an etching back process to said conductor layer until said field insulation pattern is exposed at said gap.

13. A method as claimed in claim 11, wherein said step of forming said side wall pattern includes the steps of depositing an insulation layer such that said insulation layer covers said plurality of conductive patterns including said end surfaces and such that said insulation layer fills said gap, and applying an etch back process to said insulation layer until said field insulation pattern is exposed at said gap.

14. A method of fabricating a semiconductor device, comprising the steps of:
forming a plurality of field insulation patterns on a substrate such that each of said field insulation patterns extends in a first direction;
forming a tunneling insulation film on each of active regions, said active regions being defined on said substrate between said plurality of field insulation films;
forming a conductive layer on said substrate so as to cover said plurality of field insulation patterns and said tunneling insulation films covering said active regions;
patterning said conductive layer to form a plurality of conductive patterns each extending in said first direction in correspondence to one of said plurality of active regions, said step of patterning being conducted such that each conductive pattern has an end surface located on said field oxide film and extending in said first direction, and such that said end surface faces an end surface of another conductive pattern corresponding to an adjacent active region locating across said field oxide film with a gap therebetween;
introducing an impurity element of a first conductivity type into said substrate through said field oxide patterns by an ion implantation process while using said plurality of conductive patterns as a mask;
depositing an interlayer insulation film on said substrate such that said interlayer insulation film covers said plurality of conductive patterns and said side wall patterns;
depositing a conductor layer on said interlayer insulation film generally with a uniform thickness;
patterning said conductor layer, said interlayer insulation film and further said conductive patterns underneath said interlayer insulation film, to form a plurality of gate electrode structures such that each of said gate electrode structures extends in a second direction different from said first direction, each of said gate electrode structures thereby including a floating gate electrode patterned from said conductive pattern and a control electrode patterned from said conductor layer and extending in said second direction over a plurality of said active regions, said floating gate electrode being provided in correspondence to one of said active regions and isolated from other said floating gate electrodes; and
introducing an impurity element of a second conductivity type into said substrate in each of said plurality of active regions by an ion implantation process while using said gate electrode structure as a mask, to form a diffusion region in said substrate;
said step of patterning said conductive layer to form said plurality of conductive patterns being conducted such that said edge surface has a bottom part projecting beyond a top part in each of said plurality of conductive patterns.

15. A method of fabricating a semiconductor device, comprising the steps of:
forming a plurality of field insulation patterns on a substrate such that each of said field insulation patterns extends in a first direction;
forming a gate insulation film on each of active regions, said active regions being defined on said substrate between said plurality of field insulation films;
forming a conductive layer on said substrate so as to cover said plurality of field insulation patterns and said gate insulation films covering said active regions;
patterning said conductive layer to form a plurality of conductive patterns each extending in said first direction in correspondence to one of said plurality of active regions, said step of patterning being conducted such that each conductive pattern has an end surface located on said field oxide film and extending in said first direction, and such that said end surface faces an end surface of another conductive pattern corresponding to an adjacent active region locating across said field oxide film with a gap therebetween;
forming a side wall pattern on said end surface for each of said polysilicon patterns such that said side wall pattern projects from said end surface;
introducing an impurity element of a first conductivity type into said substrate through said field oxide patterns by an ion implantation process while using said plurality of conductive patterns and said side wall patterns as a mask;
depositing a conductor layer on said conductive patterns so as to cover said conductive patterns generally with a uniform thickness;
patterning said conductor layer and said conductive patterns underneath said conductor layer, to form a plurality of gate electrode structures such that each of said gate electrode structures extends in a second direction different from said first direction, each of said gate electrode structures thereby including a gate electrode patterned from said conductive pattern and a gate interconnection electrode patterned from said conductor layer and extending in said second direction over a plurality of said active regions, said gate electrode being provided in correspondence to one of said active regions and isolated from other said gate electrodes; and
introducing an impurity element of a second conductivity type into said substrate in each of said plurality of active regions by an ion implantation process while using said gate electrode structure as a mask, to form a diffusion region in said substrate.
